(19) United States
(12) Patent Application Publication
(10) Pub. No.: US 2025/0118616 A1
(43) Pub. Date: Apr. 10, 2025

(54) SEMICONDUCTOR PACKAGE

(71) Applicant: Samsung Electronics Co., Ltd., Suwon-si (KR)

(72) Inventor: Tea-Geon Kim, Suwon-si (KR)

(21) Appl. No.: 18/608,315

(22) Filed: Mar. 18, 2024

(30) Foreign Application Priority Data
Oct. 10, 2023 (KR) 10-2023-0134141

(51) Int. Cl. H01L 23/367; H01L 23/00; H01L 23/31; H01L 23/373; H01L 25/065

(52) U.S. Cl. CPC H01L 23/367; H01L 23/3128; H01L 23/373; H01L 25/0655; H01L 24/16; H01L 24/32; H01L 24/48; H01L 24/73; H01L 24/96; H01L 24/97; H01L 2224/16225; H01L 2224/32225; H01L 2224/48227; H01L 2224/73204; H01L 2224/96; H01L 2224/97; H01L 2924/1815

(57) ABSTRACT

A semiconductor package includes a package substrate, a semiconductor chip on the package substrate, a molding layer on a top surface of the package substrate and covering a side surface and a top surface of the semiconductor chip, and a heat dissipation structure on the molding layer. The heat dissipation structure includes a plurality of concave portions facing the top surface of the package substrate. The heat dissipation structure includes a carbon nanotube and a thermosetting resin.

### CROSS-REFERENCE TO RELATED APPLICATIONS

This U.S. non-provisional patent application claims priority under 35 U.S.C. § 119 to Korean Patent Application No. 10-2023-0134141, filed on Oct. 10, 2023 in the Korean Intellectual Property Office, the entire contents of which are hereby incorporated by reference.

### BACKGROUND

The present disclosure relates to a semiconductor package, and more particularly, to a semiconductor package including a heat dissipation structure.

Recently, portable devices have been increasingly demanded in the electronics market, and thus small and light electronic components mounted in the electronics have been required. A semiconductor package technique of integrating a plurality of individual components in a single package as well as a technique of reducing a size of an individual component may be required to realize small and light electronic components. In particular, a semiconductor package in which individual components (e.g., chips) are integrated may be required to have excellent warpage characteristics, excellent heat dissipation characteristics and excellent electrical characteristics as well as a small size.

### SUMMARY

Embodiments of the inventive concepts may provide a semiconductor package with improved heat dissipation efficiency and a method of manufacturing the same.

In an aspect, a semiconductor package may include a package substrate, a semiconductor chip on the package substrate, a molding layer on a top surface of the package substrate and covering a side surface and a top surface of the semiconductor chip, and a heat dissipation structure on the molding layer. The heat dissipation structure may include a plurality of concave portions facing the top surface of the package substrate. The heat dissipation structure may include a carbon nanotube and a thermosetting resin.

In an aspect, a semiconductor package may include a package substrate, a semiconductor chip on the package substrate, a molding layer on the package substrate and covering the semiconductor chip, and a heat dissipation structure on the molding layer and vertically spaced apart from the semiconductor chip. The heat dissipation structure may include a carbon nanotube and a thermosetting resin. The thermosetting resin may be cross-linked to the molding layer.

In an aspect, a semiconductor package may include a package substrate, a semiconductor chip on the package substrate, a molding layer on a top surface of the package substrate and covering a side surface and a top surface of the semiconductor chip, and a heat dissipation structure on the molding layer and vertically spaced apart from the semiconductor chip. A bottom surface of the heat dissipation structure may include a plurality of concave portions facing the top surface of the package substrate. A surface area of the bottom surface of the heat dissipation structure may be greater than a surface area of a top surface of the heat dissipation structure. The heat dissipation structure may include a carbon nanotube and a thermosetting resin.

### BRIEF DESCRIPTION OF THE DRAWINGS

FIG. 1 is a plan view illustrating a semiconductor package according to some embodiments of the inventive concepts.

FIG. 2 is a cross-sectional view taken along a line A-A′ of FIG. 1.

FIG. 3 is an enlarged view of a portion ‘CU’ of FIG. 2.

FIG. 4 is a cross-sectional view illustrating a semiconductor package according to some embodiments of the inventive concepts.

FIGS. 5A to 5D are cross-sectional views illustrating a method of manufacturing a semiconductor package according to some embodiments of the inventive concepts.

FIGS. 6A to 6E are cross-sectional views illustrating a method of manufacturing a semiconductor package according to some embodiments of the inventive concepts.

### DETAILED DESCRIPTION

Embodiments of the inventive concepts will now be described more fully with reference to the accompanying drawings.

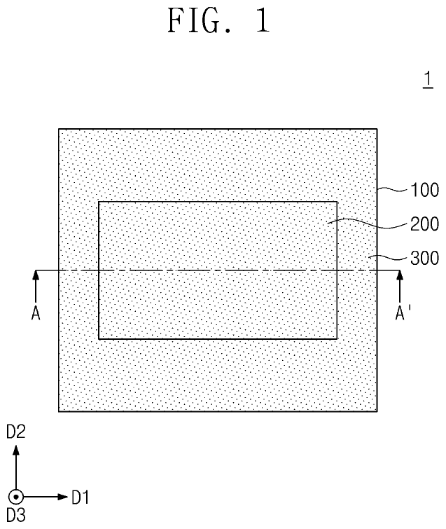

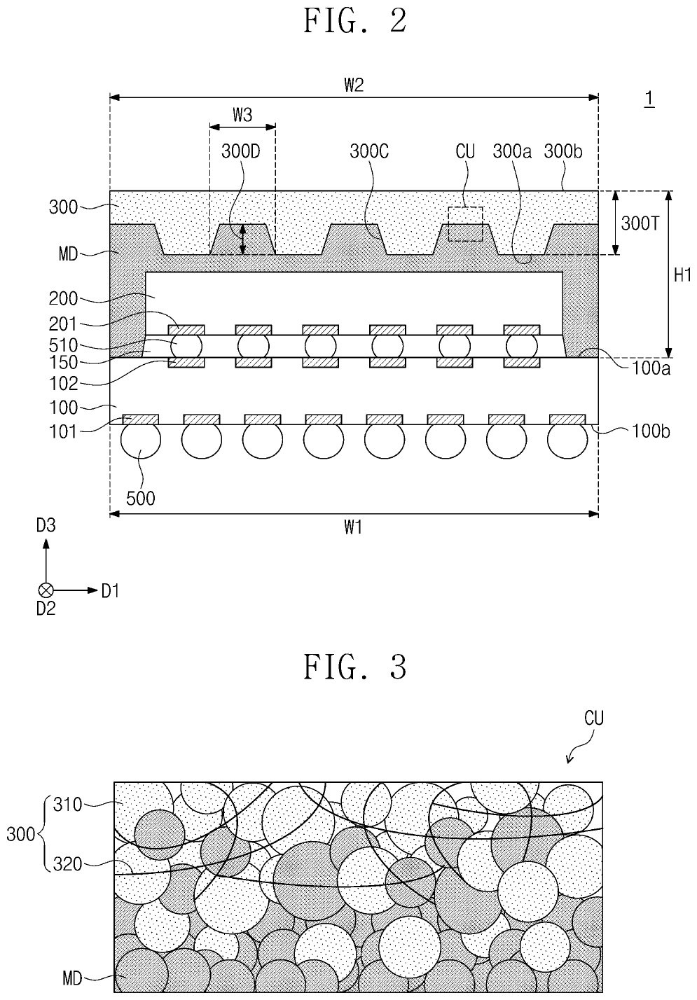

FIG. 1 is a plan view illustrating a semiconductor package according to some embodiments of the inventive concepts. FIG. 2 is a cross-sectional view taken along a line A-A of FIG. 1.

Referring to FIGS. 1 and 2, a semiconductor package 1 according to some embodiments of the inventive concepts may include a package substrate 100, a first semiconductor chip 200, a molding layer MD, and a heat dissipation structure 300.

In the present specification, a first direction D1 may be defined as a direction parallel to a top surface of the package substrate 100. A second direction D2 may be defined as a direction which is parallel to the top surface of the package substrate 100 and is perpendicular to the first direction D1. A third direction D3 may be defined as a direction perpendicular to the top surface of the package substrate 100.

For example, the package substrate 100 may be a printed circuit board (PCB). Alternatively, even though not shown in the drawings, the package substrate 100 may have a structure in which insulating layers and interconnection layers are alternately stacked. The package substrate 100 may have a first width W1 in the first direction D1. The package substrate 100 may include a first surface 100a and a second surface 100b, which are opposite to each other. The first surface 100a may correspond to the top surface of the package substrate 100. The second surface 100b may correspond to a bottom surface of the package substrate 100. The package substrate 100 may include a plurality of upper substrate pads 102 on the first surface 100a, and a plurality of lower substrate pads 101 on the second surface 100b.

External connection terminals 500 may be disposed on the lower substrate pads 101, respectively. The external connection terminals 500 may be electrically connected to an interconnection layer and the upper substrate pads 102 through the lower substrate pads 101. Each of the external connection terminals 500 may include a solder ball or a solder bump. The external connection terminals 500 may be provided in the form of a ball grid array (BGA), a fine ball-grid array (FBGA) or a land grid array (LGA) depending on a kind and/or arrangement of the external connection terminals 500. The external connection terminal 500 may include a material or an alloy including at least one of tin (Sn), silver (Ag), copper (Cu), nickel (Ni), bismuth (Bi), indium (In), antimony (Sb), and cerium (Ce).

The first semiconductor chip 200 may be disposed on the package substrate 100. For example, the first semiconductor chip 200 may be a logic chip or a memory chip. For example, the first semiconductor chip 200 may be a central processing unit (CPU), a graphics processing unit (GPU), an application specific integrated circuit (ASIC) chip, a DRAM chip, a SRAM chip, or a NAND FLASH chip. A plurality of first chip pads 201 may be disposed on a bottom surface of the first semiconductor chip 200.

Connection terminals 510 may be disposed between the package substrate 100 and the first semiconductor chip 200. More particularly, each of the connection terminals 510 may be disposed between the upper substrate pad 102 and the first chip pad 201 and may be in contact with the upper substrate pad 102 and the first chip pad 201. The first semiconductor chip 200 may be electrically connected to the package substrate 100 through the connection terminals 510. The connection terminals 510 may include the same/similar metal material as the external connection terminal 500.

An underfill layer 150 may be provided between the package substrate 100 and the first semiconductor chip 200. The underfill layer 150 may be in or fill a space between the package substrate 100 and the first semiconductor chip 200 and may surround a side surface of each of the connection terminals 510. For example, the underfill layer 150 may include an epoxy resin.

The molding layer MD may be provided to cover at least a portion of the first surface 100a of the package substrate 100, a side surface and a top surface of the first semiconductor chip 200, and a side surface of the underfill layer 150. The molding layer MD may include an insulating material, and the insulating material may include a material such as an epoxy molding compound (EMC) or may include an adhesive material.

The heat dissipation structure 300 may be disposed on the molding layer MD. The heat dissipation structure 300 may be disposed on the molding layer MD and thus may be spaced apart from the first semiconductor chip 200 in the third direction D3. A ratio of a volume of the heat dissipation structure 300 to a sum of a volume of the molding layer MD and the volume of the heat dissipation structure 300 may range from 30% to 50%. For example, a mass ratio of the molding layer MD:the heat dissipation structure 300 may be 1:1.

The heat dissipation structure 300 may include a third surface 300a and a fourth surface 300b, which are opposite to each other in the third direction D3. The third surface 300a may correspond to a bottom surface of the heat dissipation structure 300. The fourth surface 300b may correspond to a top surface of the heat dissipation structure 300. The third surface 300a of the heat dissipation structure 300 may be closer to the first surface 100a of the package substrate 100 than the fourth surface 300b.

The heat dissipation structure 300 may have a second width W2 in the first direction D1. The second width W2 of the heat dissipation structure 300 may range from 90% to 100% of the first width W1 of the package substrate 100. The heat dissipation structure 300 may have a first thickness 300T in the third direction D3. The first thickness 300T may correspond to a maximum length in the third direction D3 from the third surface 300a to the fourth surface 300b of the heat dissipation structure 300. The first thickness 300T may range from 20% to 30% of a distance H1 in the third direction D3 from the first surface 100a of the package substrate 100 to the fourth surface 300b of the heat dissipation structure 300.

The third surface 300a of the heat dissipation structure 300 may include a concave portion 300C. The concave portion 300C may be disposed in a direction facing the first surface 100a of the package substrate 100. The concave portion 300C may be provided in plurality, and the plurality of concave portions 300C may be arranged in the first direction D1 and/or the second direction D2. Since the third surface 300a of the heat dissipation structure 300 includes the concave portion 300C, a surface area of the third surface 300a may be greater than a surface area of the fourth surface 300b. For example, the surface area of the third surface 300a may be two or more times greater than the surface area of the fourth surface 300b.

The concave portion 300C may have a third width W3 in the first direction D1. The third width W3 may become progressively smaller from the third surface 300a toward the fourth surface 300b. The third width W3 of the concave portion 300C may range from 5% to 15% of the first width W1 of the package substrate 100. The concave portion 300C may have a first depth 300D in the third direction D3. The first depth 300D may range from 5% to 15% of the first width W1 of the package substrate 100. The inside of the concave portion 300C may be filled with the molding layer MD.

FIG. 3 is an enlarged view of a portion ‘CU’ of FIG. 2.

Referring to FIG. 3, the heat dissipation structure 300 disposed on the molding layer MD may include a carbon nanotube 320 and a thermosetting resin 310. More particularly, the carbon nanotubes 320 may be mixed or tangled in a network form in the thermosetting resin 310. Here, a length of the carbon nanotube 320 may range from 10 μm to 10 mm. A diameter of the carbon nanotube 320 may range from several nm to hundreds nm. An aspect ratio obtained by dividing the length of the carbon nanotube 320 by the diameter of the carbon nanotube 320 may be at least 10 or more. A polymer of the thermosetting resin 310 may be cross-linked. More particularly, a portion of the polymer of the thermosetting resin 310 and a portion of a polymer of the molding layer MD may have a cross-linking shape near an interface between the molding layer MD and the heat dissipation structure 300.

A portion of the carbon nanotube 320 may be observed or detected in the molding layer MD. A portion of the polymer of the thermosetting resin 310 may be observed or detected in the molding layer MD. A portion of the polymer of the molding layer MD may be observed or detected in the heat dissipation structure 300.

A mass ratio of the thermosetting resin 310:the carbon nanotube 320 in the heat dissipation structure 300 may range from 6:4 to 7:3. The thermosetting resin 310 may include at least one of an epoxy resin, a polyurethane resin, a silicon resin, an acrylic resin, a polyester resin, a phenolic resin, a melamine resin, and an alkyd resin.

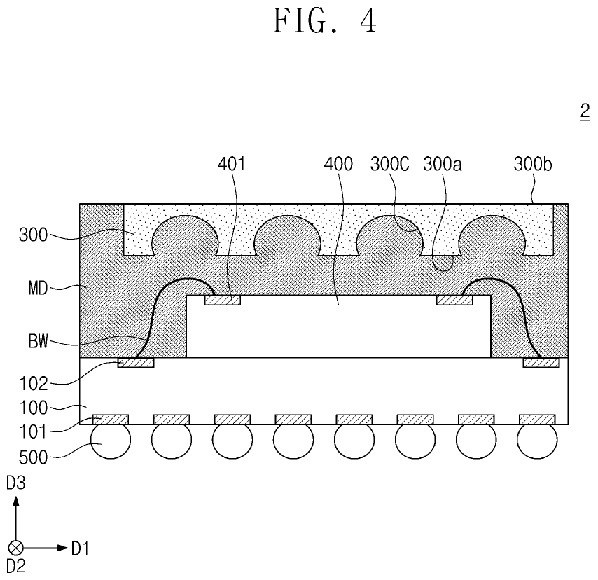

FIG. 4 is a cross-sectional view illustrating a semiconductor package according to some embodiments of the inventive concepts. Hereinafter, the descriptions to the same features as mentioned with reference to FIGS. 2 and 3 may be omitted for the purpose of ease and convenience in explanation.

Referring to FIG. 4, a semiconductor package 2 according to some embodiments of the inventive concepts may include a second semiconductor chip 400 disposed on a package substrate 100. A chip pad 401 may be disposed at a top surface of the second semiconductor chip 400. The chip pad 401 may be connected to the upper substrate pad 102 of the package substrate 100 through a bonding wire BW. In other words, the second semiconductor chip 400 may be electrically connected to the package substrate 100 by a wire bonding method.

A kind of the second semiconductor chip 400 may be the same as or different from the kind of the first semiconductor chip 200. For example, the second semiconductor chip 400 may be a logic chip or a memory chip. For example, the second semiconductor chip 400 may be a central processing unit (CPU), a graphics processing unit (GPU), an application specific integrated circuit (ASIC) chip, a DRAM chip, a SRAM chip, or a NAND FLASH chip.

A heat dissipation structure 300 may be disposed on a molding layer MD. A vertical level of a top surface of the molding layer MD may be substantially the same as a vertical level of a top surface of the heat dissipation structure 300. The top surface of the molding layer MD and the top surface of the heat dissipation structure 300 may be coplanar or substantially coplanar. A shape of a cross section of a concave portion 300C shown in FIG. 4 may be a shape similar to a circle or an approximate semicircle (e.g., rounded), but embodiments of the inventive concepts are not limited thereto. In certain embodiments, the shape of the cross section of the concave portion 300C may be a circular shape or a polygonal shape.

The semiconductor package according to the embodiments of the inventive concepts may include the heat dissipation structure 300 on the molding layer MD. The heat dissipation structure 300 may include the carbon nanotube 320 and the thermosetting resin 310. Here, the carbon nanotubes 320 may be tangled in the network form in the thermosetting resin 310. The carbon nanotube 320 may have high thermal conductivity and the high aspect ratio, and thus heat generated from the semiconductor chip may be rapidly dissipated or released to the outside through the carbon nanotube 320.

In addition, the third surface 300a of the heat dissipation structure 300 may include a plurality of the concave portions 300C. Due to the concave portion 300C, the surface area of the third surface 300a of the heat dissipation structure 300 may be greater than the surface area of the fourth surface 300b. As a result, heat generated from the semiconductor chip may be effectively dissipated or released along the wide surface area of the third surface 300a.

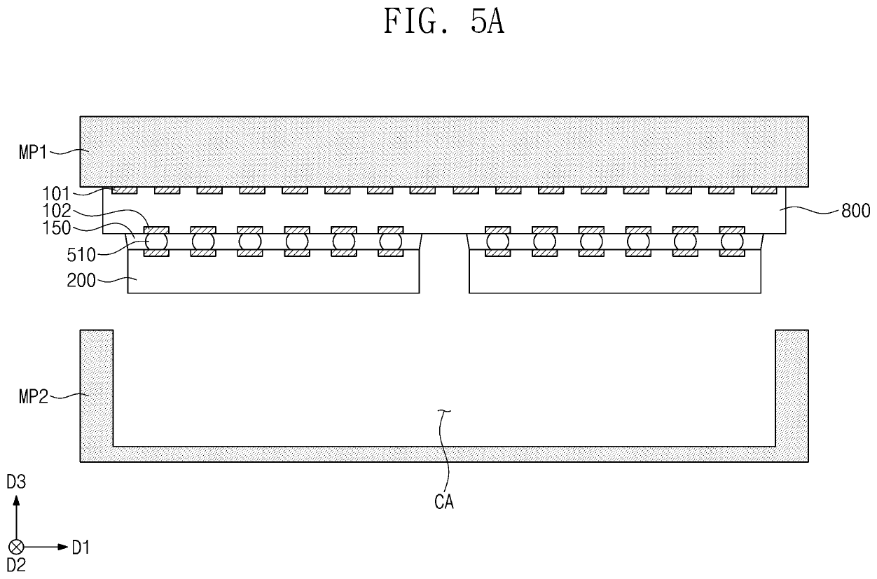

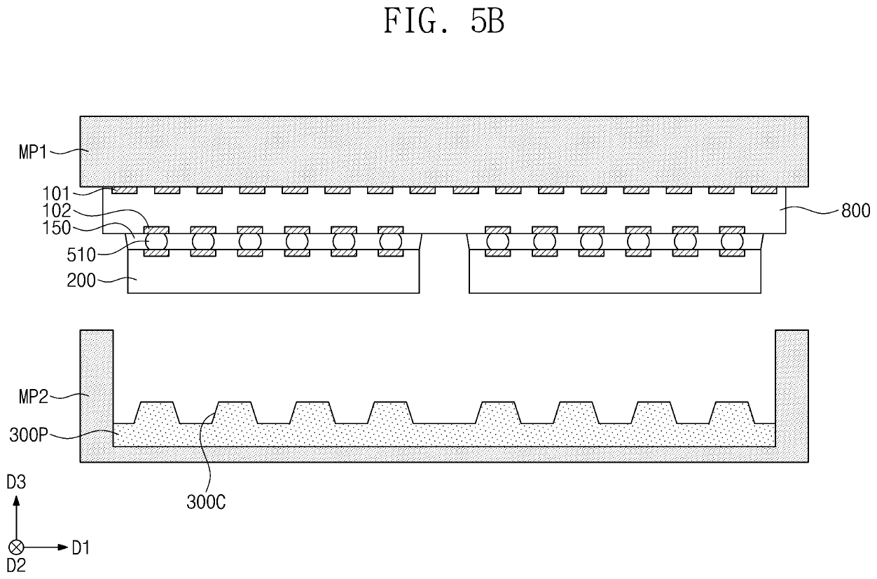

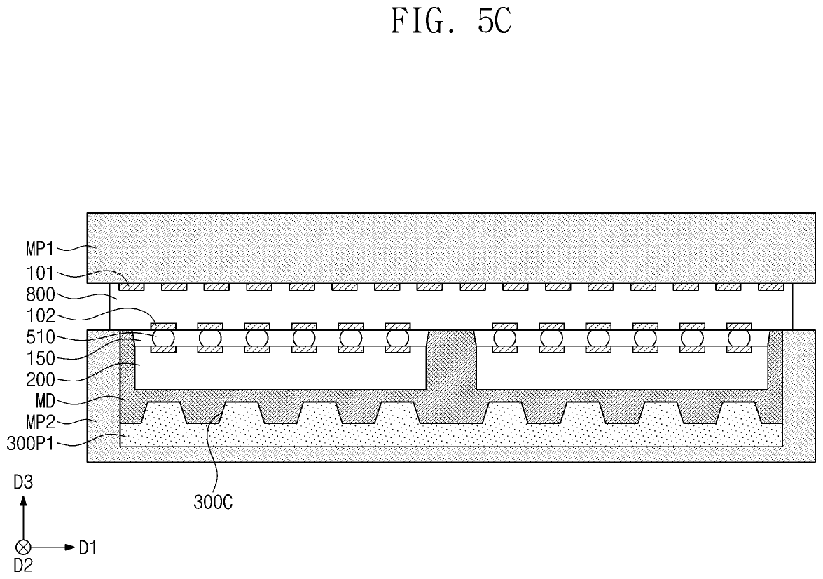

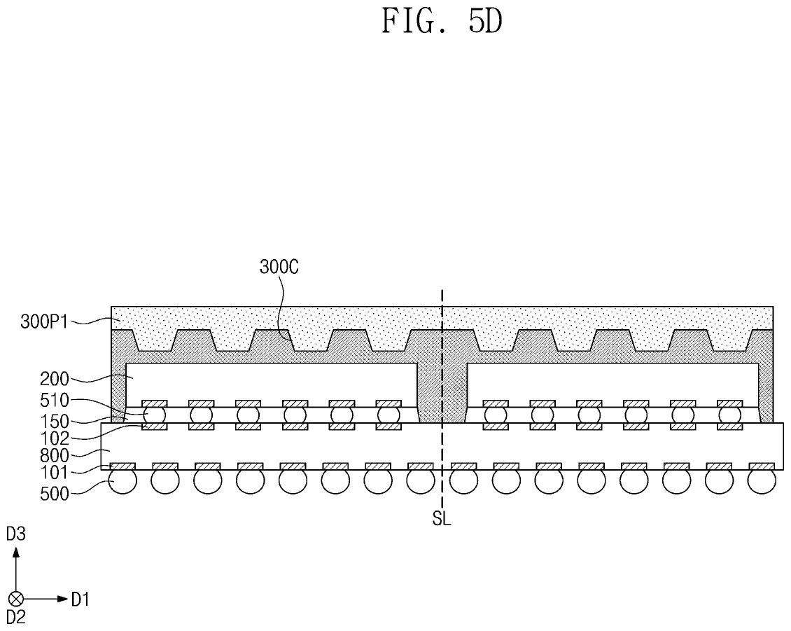

FIGS. 5A to 5D are cross-sectional views illustrating a method of manufacturing a semiconductor package according to some embodiments of the inventive concepts. More particularly, FIGS. 5A to 5D are cross-sectional views illustrating a method of manufacturing the semiconductor package 1 shown in FIG. 2.

Referring to FIG. 5A, a printed circuit board 800 and a plurality of first semiconductor chips 200 on the printed circuit board 800 may be provided.

Thereafter, a first mold frame MP1 and a second mold frame MP2 including a cavity CA may be provided. The printed circuit board 800 and the first semiconductor chips 200 may be turned over and may be adsorbed to one surface of the first mold frame MP1. The adsorption process may be performed in a vacuum state.

Referring to FIG. 5B, a first mixture 300P may be provided on a bottom surface of the cavity CA. Even though not shown in the drawings, a release film may be provided on the bottom surface of the cavity CA before providing the first mixture 300P. The first mixture 300P may be provided in a state in which concave portions 300C are formed along the first direction D1 and/or the second direction D2. The first mixture 300P may be powder in which the carbon nanotubes 320 and the thermosetting resin 310 described in FIG. 3 are mixed with each other.

Referring to FIG. 5C, molding powder (not shown) may be provided in a remaining space of the cavity CA of the second mold frame MP2 except the first mixture 300P. The molding powder may be provided on the first mixture 300P to fill the cavity CA. The first mold frame MP1 may be moved in the third direction D3 so as to be adjacent to the second mold frame MP2. Since the first mold frame MP1 is moved, a portion of an edge of the printed circuit board 800 may be in contact with the second mold frame MP2.

A thermal treatment process may be performed on the molding powder and the first mixture 300P. The molding powder may flow due to the thermal treatment process to fill the inside of the concave portion 300C. Thereafter, the molding powder and the first mixture 300P may be hardened to form a molding layer MD and a preliminary heat dissipation structure 300P1 at the same time.

Referring to FIG. 5D, the first mold frame MP1 and the second mold frame MP2 may be removed in the state in which the molding layer MD and the preliminary heat dissipation structure 300P1 are formed on the printed circuit board 800. An external connection terminal 500 may be formed on a lower substrate pad 101. Thereafter, the printed circuit board 800 and the first semiconductor chips 200 may be turned over, and then, the printed circuit board 800, the molding layer MD and the preliminary heat dissipation structure 300P1 may be cut along a sawing line SL. By the cutting process, a package substrate 100 and a heat dissipation structure 300 may be formed from the printed circuit board 800 and the preliminary heat dissipation structure 300P1, respectively. As a result, the semiconductor package 1 according to the embodiments of the inventive concepts may be completed.

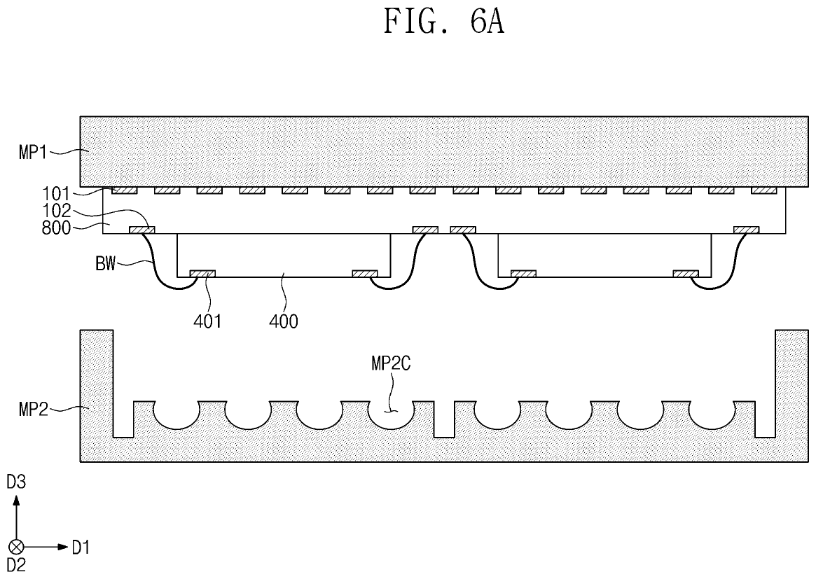

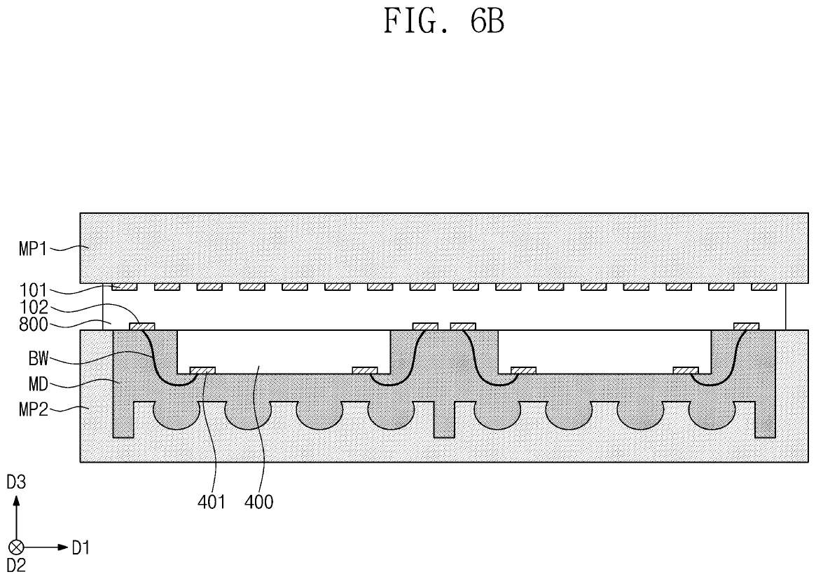

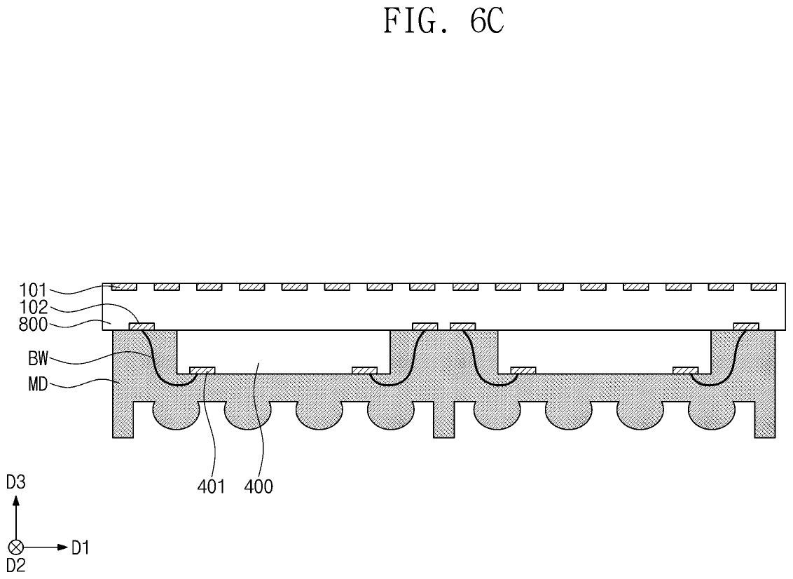

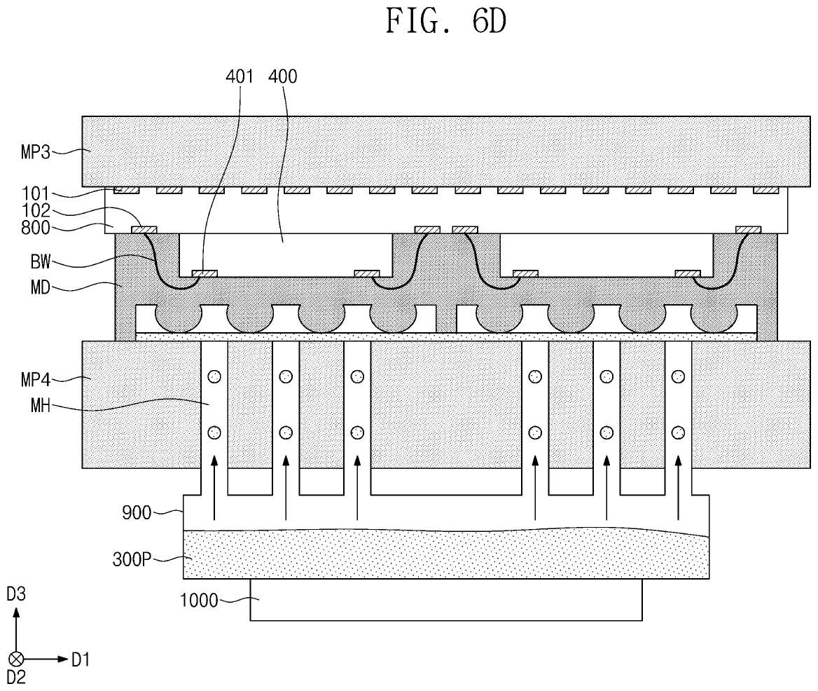

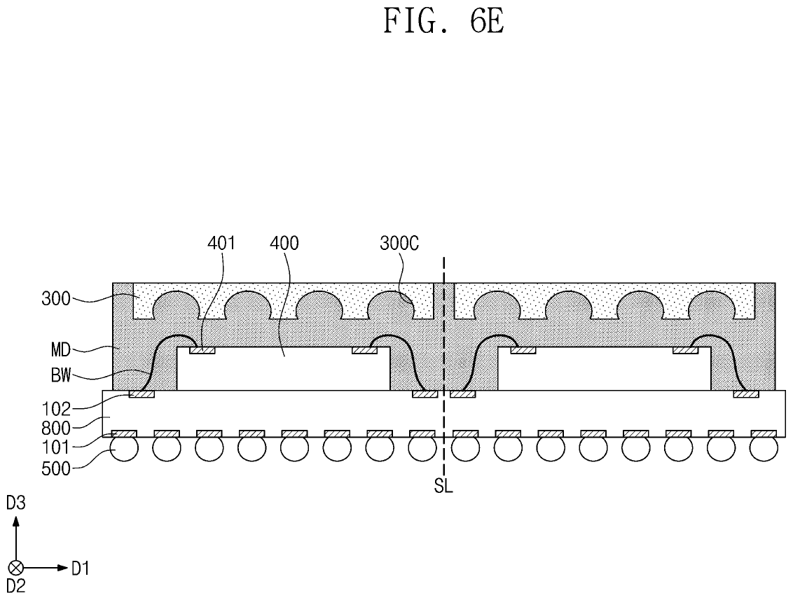

FIGS. 6A to 6E are cross-sectional views illustrating a method of manufacturing a semiconductor package according to some embodiments of the inventive concepts. More particularly, FIGS. 6A to 6E are cross-sectional views illustrating a method of manufacturing the semiconductor package 2 shown in FIG. 4.

Referring to FIG. 6A, a plurality of second semiconductor chips 400 may be provided on a printed circuit board 800. The printed circuit board 800 may be substantially the same as described with reference to FIG. 5A. The second semiconductor chips 400 may be connected to the printed circuit board 800 through bonding wires BW.

Thereafter, a first mold frame MP1 and a second mold frame MP2 including a plurality of mold concave portions MP2C may be provided. The printed circuit board 800 and the second semiconductor chips 400 may be turned over and may be adsorbed to one surface of the first mold frame MP1. The adsorption process may be performed in a vacuum state.

Referring to FIG. 6B, molding powder (not shown) may be provided on the second mold frame MP2. The molding powder may fill the plurality of mold concave portions MP2C and an empty space in the second mold frame MP2. The first mold frame MP1 may be moved in the third direction D3 so as to be adjacent to the second mold frame MP2. Since the first mold frame MP1 is moved, a portion of an edge of the printed circuit board 800 may be in contact with the second mold frame MP2.

Thereafter, a thermal treatment process may be performed on the molding powder. The molding powder may be hardened by the thermal treatment process, thereby forming a molding layer MD.

Referring to FIG. 6C, the first mold frame MP1 adsorbed to one surface of the printed circuit board 800 and the second mold frame MP2 surrounding the molding layer MD may be removed. At this time, a shape of a portion of the molding layer MD may be a shape filling the inside of the mold concave portion MP2C described in FIG. 6A.

Referring to FIG. 6D, a third mold frame MP3 and a fourth mold frame MP4 may be adsorbed onto the one surface of the printed circuit board 800 and an edge region of the molding layer MD, respectively. Since the fourth mold frame MP4 is adsorbed onto the edge region of the molding layer MD, an empty space may be formed between the molding layer MD and the fourth mold frame MP4.

A hydraulic pump 1000, a hopper 900 and a cylinder MH may be provided. The hydraulic pump 1000, the hopper 900 and the cylinder MH may be a portion of an injection apparatus. More particularly, the cylinder MH may be connected to the hopper 900, and a portion of the cylinder MH may penetrate a portion of the fourth mold frame MP4. A first mixture 300P may be provided in the hopper 900. The first mixture 300P may be powder in which the carbon nanotubes 320 and the thermosetting resin 310 described in FIG. 3 are mixed with each other.

The first mixture 300P provided in the hopper 900 may be moved in the third direction D3 through the cylinder MH by the driving force of the hydraulic pump 1000. The moved first mixture 300P may fill the empty space between the molding layer MD and the fourth mold frame MP4.

Referring to FIG. 6E, a thermal treatment process may be performed on the first mixture 300P. The first mixture 300P may be hardened by the thermal treatment process, thereby forming a plurality of heat dissipation structures 300.

The third mold frame MP3 and the fourth mold frame MP4 may be removed in the state in which the molding layer MD and the heat dissipation structures 300 are formed on the printed circuit board 800. An external connection terminal 500 may be formed on a lower substrate pad 101. Thereafter, the printed circuit board 800 and the second semiconductor chips 400 may be turned over, and then, the printed circuit board 800 and the molding layer MD may be cut along a sawing line SL. By the cutting process, a package substrate 100 may be formed from the printed circuit board 800. As a result, the semiconductor package 2 according to the embodiments of the inventive concepts may be completed.

In the method of manufacturing a semiconductor package according to the embodiments of the inventive concepts, the first mixture 300P may be provided in the cavity CA of the second mold frame MP2, and the molding powder may be provided on the first mixture 300P. Thereafter, the thermal treatment process may be performed on the first mixture 300P and the molding powder. The molding powder and the first mixture 300P may be hardened by the thermal treatment process to form the molding layer MD and the heat dissipation structure 300 at the same time.

At this time, bonding strength between the molding layer MD and the thermosetting resin 310 included in the heat dissipation structure 300 may be increased by cross-linking formed in the thermal treatment process. As a result, it is possible to prevent the heat dissipation structure 300 from being separated from the molding layer MD, and thus structural stability of the semiconductor package may be improved.

The semiconductor package according to the embodiments of the inventive concepts may include the heat dissipation structure on the molding layer. The heat dissipation structure may include the carbon nanotube and the thermosetting resin. Thus, heat generated from the semiconductor chip may be rapidly dissipated or released to the outside through the carbon nanotube. In addition, a portion of the polymer of the thermosetting resin may be cross-linked to a portion of the polymer of the molding layer. As a result, the bonding strength between the heat dissipation structure and the molding layer may be increased to improve the structural stability of the semiconductor package.

Furthermore, the bottom surface of the heat dissipation structure may include the plurality of concave portions facing the top surface of the package substrate. The surface area of the bottom surface of the heat dissipation structure may be widened by the concave portions. As a result, heat generated from the semiconductor chip may be effectively dissipated or released along the wide surface area of the bottom surface of the heat dissipation structure.

While the embodiments of the inventive concepts have been particularly shown and described, it will be understood by one of ordinary skill in the art that variations in form and detail may be made therein without departing from the spirit and scope of the attached claims

What is claimed is:

1. A semiconductor package comprising:
a package substrate;
a semiconductor chip on the package substrate;
a molding layer on a top surface of the package substrate and covering a side surface and a top surface of the semiconductor chip; and
a heat dissipation structure on the molding layer,
wherein the heat dissipation structure includes a plurality of concave portions facing the top surface of the package substrate, and
wherein the heat dissipation structure includes a carbon nanotube and a thermosetting resin.

2. The semiconductor package of claim 1, wherein the package substrate has a first width in a first direction parallel to the top surface of the package substrate,
wherein the heat dissipation structure has a second width in the first direction, and
wherein the second width ranges from 90% to 100% of the first width.

3. The semiconductor package of claim 2, wherein a thickness of the heat dissipation structure ranges from 20% to 30% of a distance from the top surface of the package substrate to a top surface of the heat dissipation structure in a second direction perpendicular to the top surface of the package substrate.

4. The semiconductor package of claim 2, wherein a respective one of the concave portions has a third width in the first direction, and
wherein the third width ranges from 5% to 15% of the first width.

5. The semiconductor package of claim 3, wherein a respective one of the concave portions has a first depth in the second direction, and
wherein the first depth ranges from 5% to 15% of the first width.

6. The semiconductor package of claim 1, wherein a length of the carbon nanotube in the heat dissipation structure ranges from 10 μm to 10 mm.

7. The semiconductor package of claim 1, wherein a mass ratio of the thermosetting resin:the carbon nanotube in the heat dissipation structure ranges from 6:4 to 7:3.

8. The semiconductor package of claim 1, wherein the thermosetting resin includes at least one of an epoxy resin, a polyurethane resin, a silicon resin, an acrylic resin, a polyester resin, a phenolic resin, a melamine resin, and an alkyd resin.

9. The semiconductor package of claim 4, wherein the third width becomes progressively smaller toward a top surface of the heat dissipation structure.

10. A semiconductor package comprising:
a package substrate;
a semiconductor chip on the package substrate;
a molding layer on the package substrate and covering the semiconductor chip; and
a heat dissipation structure on the molding layer and vertically spaced apart from the semiconductor chip,
wherein the heat dissipation structure includes a carbon nanotube and a thermosetting resin, and
wherein the thermosetting resin is cross-linked to the molding layer.

11. The semiconductor package of claim 10, wherein the heat dissipation structure includes a concave portion facing a top surface of the package substrate, and
wherein a shape of a cross section of the concave portion is a circular shape or a polygonal shape.

12. The semiconductor package of claim 10, wherein a length of the carbon nanotube in the heat dissipation structure ranges from 10 μm to 10 mm.

13. The semiconductor package of claim 10, wherein a mass ratio of the thermosetting resin:the carbon nanotube in the heat dissipation structure ranges from 6:4 to 7:3.

14. The semiconductor package of claim 11, wherein the concave portion is filled with the molding layer.

15. The semiconductor package of claim 11, wherein the concave portion comprises a plurality of concave portions, and the concave portions are arranged in a first direction and a second direction, which are parallel to the top surface of the package substrate and are perpendicular to each other.

16. A semiconductor package comprising:
a package substrate;
a semiconductor chip on the package substrate;
a molding layer on a top surface of the package substrate and covering a side surface and a top surface of the semiconductor chip; and
a heat dissipation structure on the molding layer and vertically spaced apart from the semiconductor chip,
wherein a bottom surface of the heat dissipation structure includes a plurality of concave portions facing the top surface of the package substrate,
wherein a surface area of the bottom surface of the heat dissipation structure is greater than a surface area of a top surface of the heat dissipation structure, and
wherein the heat dissipation structure includes a carbon nanotube and a thermosetting resin.

17. The semiconductor package of claim 16, wherein a ratio of a volume of the heat dissipation structure to a sum of a volume of the molding layer and the volume of the heat dissipation structure ranges from 30% to 50%.

18. The semiconductor package of claim 16, wherein a top surface of the molding layer is substantially coplanar with the top surface of the heat dissipation structure.

19. The semiconductor package of claim 16, wherein the thermosetting resin includes at least one of an epoxy resin, a polyurethane resin, a silicon resin, an acrylic resin, a polyester resin, a phenolic resin, a melamine resin, and an alkyd resin.

20. The semiconductor package of claim 16, wherein the concave portions are arranged in a first direction and a second direction, which are parallel to the top surface of the package substrate and are perpendicular to each other.
